(19) United States
(12) Patent Application Publication
(10) Pub. No.: US 2015/0293176 A1
(43) Pub. Date: Oct. 15, 2015

(54) TESTING APPRATUS FOR SAFETY SWITCHES AND METHOD

(71) Applicant: SARAH LOUISE ALLEN AS TRUSTEE FOR THE ALLEN FAMILY TRUST, Sandringham, Victoria (AU)

(72) Inventors: Kevin Robert Wilson, Aspendale Gardens (AU); Ainslie Kenneth Allen, Sandringham (AU)

(21) Appl. No.: 14/434,706

(22) PCT Filed: Oct. 10, 2013
(86) PCT No.: PCT/AU2013/001179

§ 371 Date: Apr. 9, 2015

(30) Foreign Application Priority Data
Oct. 12, 2012 (AU) 2012904478

(51) Int. Cl. G01R 31/327; G01R 31/333

(52) U.S. Cl. CPC G01R 31/3277; G01R 31/3333

(57) ABSTRACT

An interface apparatus is disclosed for interfacing a testing device to a plurality of safety switches at a switch location, wherein each safety switch is connected to an electrical load circuit including at least an active line and a neutral return line. The interface apparatus comprises a plurality of actuating devices each being connectable to a respective safety switch, and a controller for controlling each actuating device to selectively connect the associated safety switch to the testing device. Each safety switch may include an RCD or RCCB device. A method of interfacing a testing device to a plurality of safety switches is also disclosed.

### CROSS-REFERENCE TO RELATED APPLICATIONS

This application is a national phase entry under 35 U.S.C. §371 of International Patent Application PCT/AU2013/001179, filed Oct. 10, 2013, designating the United States of America and published in English as International Patent Publication WO 2014/056042 A1 on Apr. 17, 2014, which claims the benefit under Article 8 of the Patent Cooperation Treaty to Australian Application Serial No. 2012904478, filed Oct. 12, 2012, the disclosure of each of which is hereby incorporated herein in its entirety by this reference.

### TECHNICAL FIELD

The present invention relates broadly to safety devices known as residual current devices (RCDs) or residual current circuit breakers (RCCBs) and in particular relates to an interface apparatus for interfacing a testing device to a plurality of safety switches or circuit breakers.

### BACKGROUND

An RCD or RCCB is a device that disconnects an associated load circuit whenever it detects that an electric current is leaking out of the circuit, such as current leaking to earth through a ground fault. Such devices are intended to operate quickly so that when a person contacts a live conductor, the circuit is isolated before electric shock can drive the heart into ventricular fibrillation, which may cause death in some circumstances. Most RCD/RCCB devices are designed to trip when a leakage current that exceeds a threshold such as 30 mA (milliamps) is detected.

Because RCD/RCCB devices are important in saving people's lives, their integrity is required to be tested on a regular basis. Although RCD devices have built-in testing circuits these generally require a user to push and hold a button on the RCD device which bleeds off approximately 200% of rated leakage current over a period of time that the button is pressed or until the associated circuit is tripped by simulating a current leaking to earth. This may indicate that the RCD trips but it may not trip at the rated leakage current thereby placing lives at risk.

In Australia, RCD device manufacturers typically require that a “push-button” test be performed monthly in the case of fixed equipment, or in the case of portable equipment, each time that the equipment is used. This may be a time-consuming process which can cause significant inconvenience to commercial premises or households.

Australian Occupational Health and Safety (OH&S) Regulations recommend that a “push-button” test be performed every 6 months. Recommendations and regulations may differ in other jurisdictions around the world.

Applicants have identified the time-consuming nature of RCD/RCCB device field testing and the expense and personal risk of an electrician testing at a live open switchboard as significant factors contributing to the inconvenience and risk involved in testing of RCD/RCCB devices.

The present invention may at least alleviate the aforementioned disadvantages by providing a quicker, more convenient and safer alternative to traditional testing of RCD/RCCB devices.

A reference herein to a patent document or other matter which is given as prior art is not to be taken as an admission that that document or matter was known or that the information it contains was part of the common general knowledge in Australia or elsewhere as at the priority date of any of the disclosure or claims herein. Such discussion of prior art in this specification is included to explain the context of the present invention in terms of the inventor's knowledge and experience.

Throughout the description and claims of this specification the words “comprise” or “include” and variations of those words, such as “comprises,” “includes” and “comprising” or “including,” are not intended to exclude other additives, components, integers or steps.

### BRIEF SUMMARY

According to one aspect of the present invention there is provided an interface apparatus for interfacing a testing device to a plurality of safety switches at a switch location, wherein each safety switch is connected to an electrical load circuit including at least an active line and a neutral return line, the interface apparatus comprising:
a plurality of actuating devices each being connectable to a respective safety switch; and
a controller for controlling each actuating device to selectively connect the associated safety switch to the testing device.

Each safety switch may include an RCD or RCCB device or other safety switch or Ground Fault Interrupter device. Each actuating device may include a controllable relay for selectively connecting the associated safety switch to the testing device. The controller may include a microprocessor or microcontroller.

The interface apparatus may include a line monitoring circuit for detecting an active line associated with a safety switch. The line monitoring circuit may be associated with the controller to prevent a safety switch from being connected to the testing device until the safety switch is clear of active line voltage.

The testing device may be adapted to measure and/or record a trip time and/or a trip current associated with a safety switch. The testing device may include a manual or an automatic device. The switch location may include a mains switchboard or the like. In some embodiments the interface apparatus may include means for interfacing to another like interface apparatus.

The testing device may be adapted to communicate with a digital computer such as a portable PC or tablet computer. The digital computer may include computer software including a control application for controlling the interface apparatus.

The digital computer and control application may communicate with the interface apparatus to select a particular RCD or RCCB device to allow it to be tested. The apparatus may include a facility to record the results of a test.

According to a further aspect of the present invention, there is provided a method of interfacing a testing device to a plurality of safety switches at a switch location, wherein each safety switch is connected to an electrical load circuit including at least an active line and a neutral return line, the method comprising:
providing a plurality of actuating devices each being connectable to a respective safety switch; and
controlling each actuating device to selectively connect the associated safety switch to the testing device.

The present invention may also provide a method of testing a safety switch such as an RCD or RCCB device including a method of interfacing a testing device to one or more safety switches as described herein.

### BRIEF DESCRIPTION OF THE DRAWINGS

Preferred embodiments of the present invention will now be described with reference to the accompanying drawings wherein:

FIG. 1 shows a safety switch being tested at a switchboard in accordance with an embodiment of the present invention;

FIG. 2 shows testing apparatus connected to RCD devices in accordance with an embodiment of the present invention;

FIG. 3 shows a block diagram of one form of interface apparatus according to the present invention;

FIG. 4 shows a flow chart of associated software; and

FIGS. 5 through 8 show block diagrams of various testing protocols including interface apparatus, according to the present invention

### DETAILED DESCRIPTION

The following detailed description of a preferred embodiment of the invention refers to the accompanying drawings. Although the description includes exemplary embodiments, other embodiments are possible and changes may be made to described embodiments without departing from the spirit and scope of the invention.

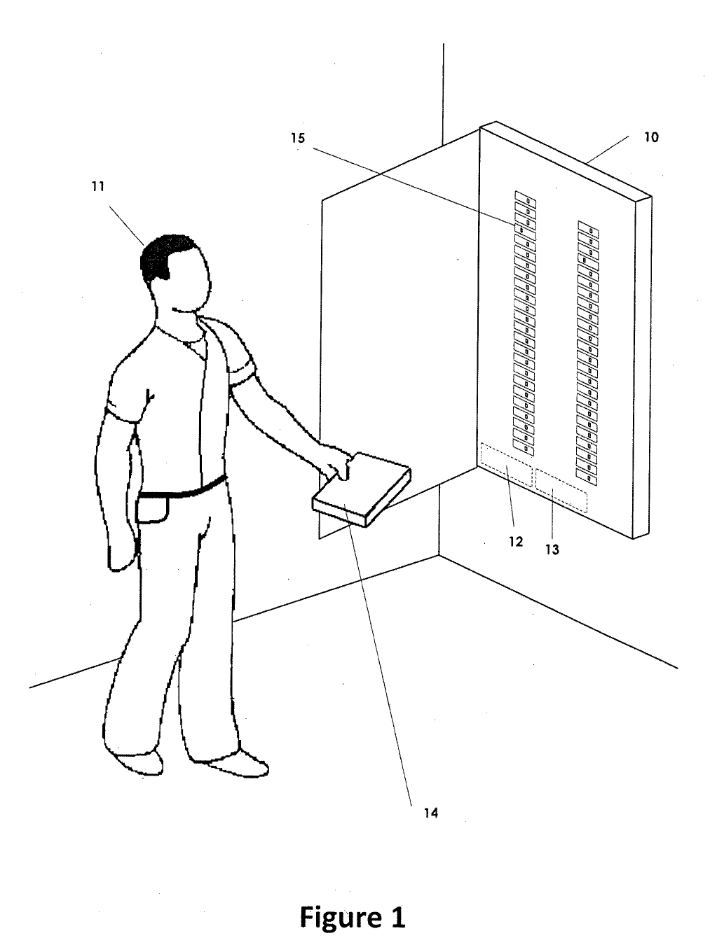

FIG. 1 shows RCD device 15 associated with switchboard 10 being tested by a technician 11. Switchboard 10 includes pre-installed testing module 12 and one or more pre-installed interface modules 13 in accordance with the present invention. Testing module 12 and interface modules 13 interact with RCD devices installed to switchboard 10 to allow each RCD device to be tested via testing module 12. A testing sequence may be initiated via handheld tablet computer 14 with control software, which communicates with testing module 12 via a wireless link such as Wi-Fi LAN or Bluetooth. In some embodiments the wireless communications link may be replaced with a communications cable which may include a serial, LAN or other standard interface.

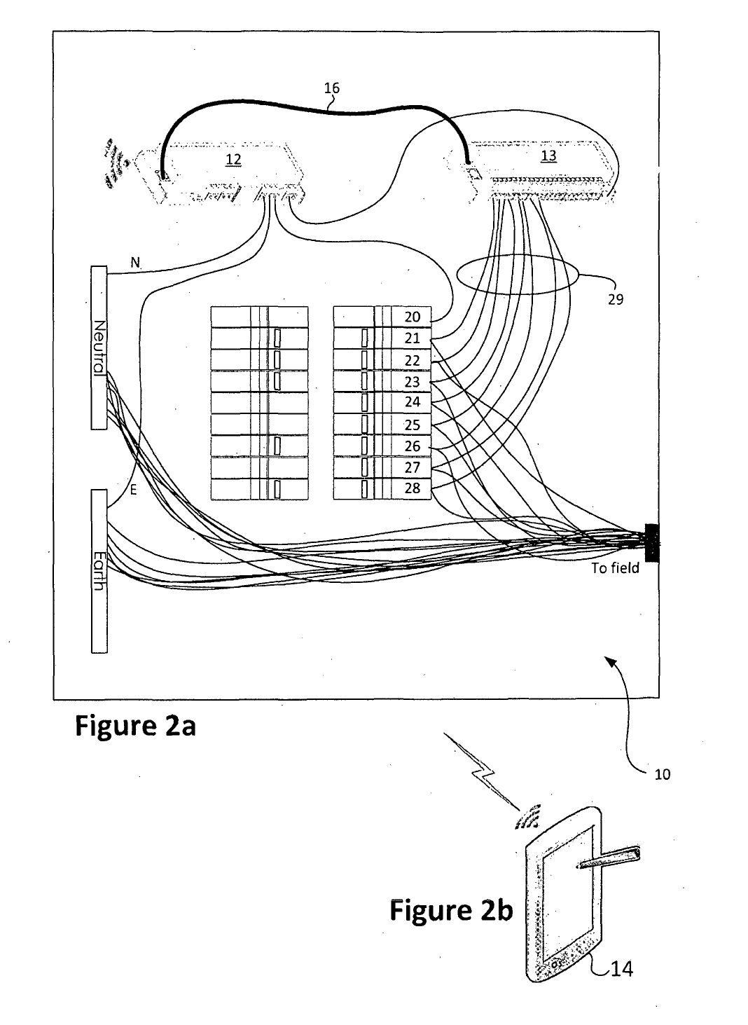

FIG. 2 is a diagram showing a plurality of RCD devices 21-28 installed to switchboard 10 and connected to interface module 13 via conducting lines 29. Testing module 12 and interface module 13 may include a configurable printed circuit board (PCB) populated with actuating devices/relays, solid state devices and/or other controllable devices. Testing module 12 is connected to interface module 13 via a communication cable 16. Testing module 12 is powered from local circuit protection device 20, as well as earth wire E and neutral wire N associated with switchboard 10. Interface module 13 is adapted via communications from testing module 12 to select each RCD device (21-28) in turn for testing under control of tablet computer 14.

Because each RCD device (21-28) is connectable to testing module 12 via interface module 13 at switchboard 10, the requirement for a technician to perform local testing or time-consuming field testing may be avoided. Once tested, the associated load circuits may be immediately reset and returned to service thereby minimizing down time and/or a requirement for testing after hours.

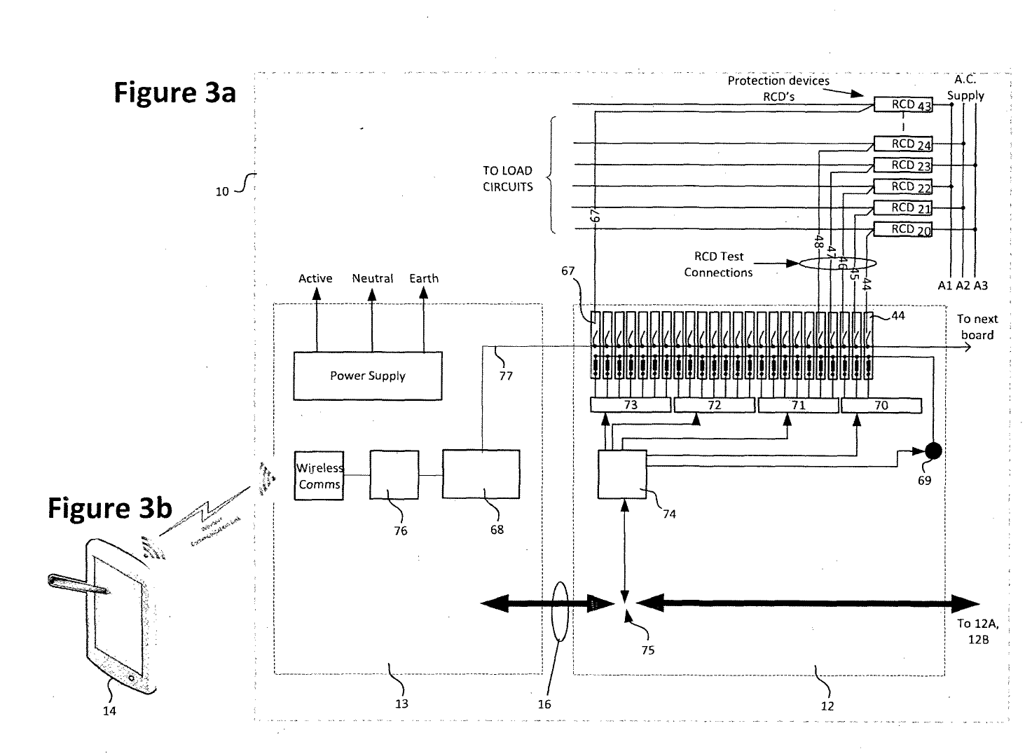

FIG. 3 shows a block diagram of one form of interface apparatus, according to the present invention, connected at switchboard 10 to a plurality of RCD devices 20-43. RCD devices 20-43 are installed at switchboard 10 between 3 phase active lines A1-A3 and respective loads circuits (not shown). The interface module 12 communicates with testing module 13 via communications cable 16. Testing module 13 is connected to digital (tablet) computer 14 via wireless communications with control software for controlling interface module 12. In some embodiments testing module 13 may include a stand-alone testing device with inbuilt intelligence.

Interface module 12 includes 24 controllable actuating devices 44-67 each comprising a relay. In some embodiments actuating devices 44-67 may comprise solid state devices such as transistors. Interface module 12 also includes line test circuit 68, power enable circuit 69, driver modules 70-73, microprocessor unit 74 and communications bus 75.

Microprocessor unit 74 is adapted to perform data storage, monitoring and control functions. Relays 44-67 are adapted to connect RCD devices 20-43, respectively, to testing module 13 when actuated under control of testing module 13 and microprocessor 74.

Line test circuit 68 ensures that status of line 77 is known prior to activating a relay (44-67) associated with RCD devices 20-43. Line test circuit 68 may detect status of line 77 regardless of which relay (44-67) or which interface module 12 (assuming that multiple interface modules are used) is supplying line voltage. Power enable circuit 69 prevents a relay channel associated with relays 44-67 from being activated without the control software first enabling interface module 12.

Microprocessor unit 74 associated with interface module 12 and/or microprocessor unit 76 associated with testing module 13 may be programmed with data identifying each relay channel (44-67) and its association with a specific RCD device (20-43). This data may be required because typically RCD devices may not occupy an entire switchboard and some RCD devices may be added at a later time.

Microprocessor unit 74 communicates with testing module 13 via communications bus 75 and cable 16. Testing module 13 may facilitate selection of each RCD device (20-43) to be tested in turn, reset and the results recorded in a database. A relay channel may not be activated until a line test has been performed ensuring that status of line 77 is not already active due to it not being turned off under a fault condition.

Interface module 12 may be connected in daisy chain fashion to one or more like interface modules 12A and 12B, etc. Multiple interface modules 12, 12A, 12B etc., may be installed in a networked configuration facilitating extension of switchboard capacities beyond that of an individual interface module 12 (24 in the example given in FIG. 3).

Digital computer 14 may include software having a control application which may initiate a test sequence and automatically record the results, as distinct to a manual test sequence. The results may be transmitted via a communications network such as the internet to a remote database facility allowing for detailed reports to be compiled about RCD devices. In some embodiments digital computer 14 or at least some of its functions may be integrated with interface module 12 and/or testing module 13.

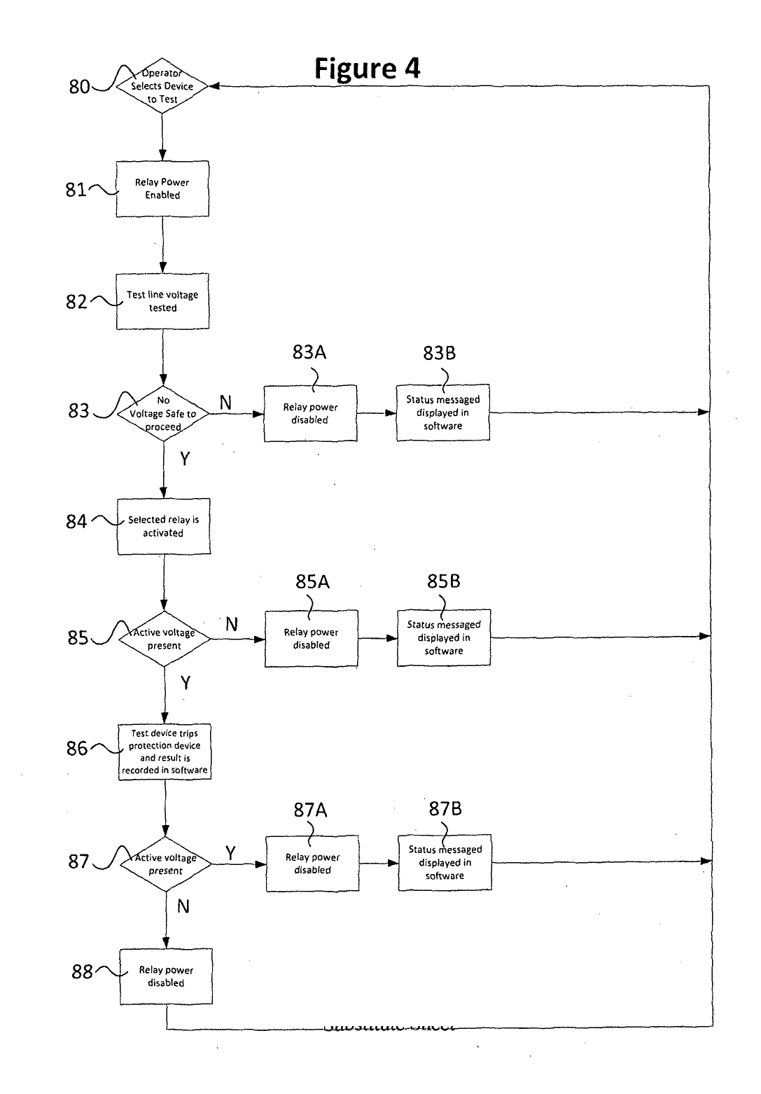

FIG. 4 shows a flow chart for an associated software application. The software application includes device selection step 80 during which an operator selects an RCD device (from devices 20-43, for example) to be tested. Step 81 is a relay power enable step during which power to coils of relays 44-67 is enabled via power enable circuit 69.

Step 82 is test line voltage step during which line test circuit 77 samples the voltage on line 68. If no voltage is detected at step 83 the selected relay (44-67) is activated at step 84 via a corresponding driver (70-73). At this stage active voltage should be present on line 68 and this is confirmed at step 85. If active voltage is present at step 85 test module 13 trips the selected RCD device (20-43) at step 86, which corresponds to the selected relay (44-67) and the result is recorded in a data base. At this stage active voltage should not be present on line 68 and this is confirmed at step 87. If no active voltage is present at line 68 power to relays 44-67 is disabled at step 88 and the software loops back to step 80.

If active voltage is detected at step 83, power to relays 44-67 is disabled at step 83A, status message is displayed at step 83B and the software loops back to step 80. If no active voltage is detected at step 85, power to relays 44-67 is disabled at step 85A, status message is displayed at step 85B and the software loops back to step 80. If active voltage is detected at step 87, power to relays 44-67 is disabled at step 87A, status message is displayed at step 87B and the software loops back to step 80.

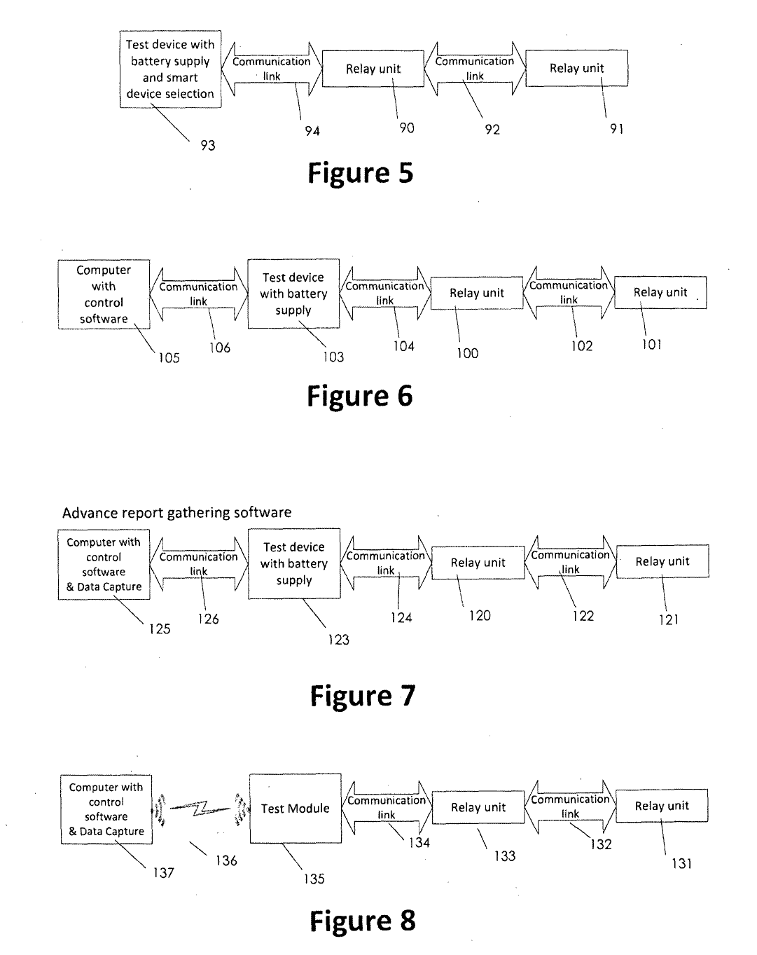

FIG. 5 is a block diagram showing multiple interface modules (relay units) 90, 91 communicating via a communication link 92 and adapted to interface with a plurality of RCD devices at a switchboard or the like (not shown). Each interface module 90, 91 may include an interface such as interface module 13 and communicates with testing device 93 via communication link 94. Testing device 93 includes a battery power supply and smart selection of RCD devices for testing. Once tested, the associated load circuit may be immediately reset minimizing down time.

FIG. 6 is a block diagram showing multiple interface modules (relay units) 100, 101 communicating via communication link 102 and adapted to interface with a plurality of RCD devices at a switchboard or the like (not shown). Each interface module 100, 101 may include an interface such as interface module 13 and communicates with testing device 103 via communication link 104. Testing device 103 includes a battery power supply and communicates with digital computer 105 via communication link 106. Digital computer 105 includes control software to facilitate smart or automatic selection of RCD devices for testing. Once tested, the associated load circuit may be immediately reset minimizing down time.

FIG. 7 is a block diagram showing multiple interface modules (relay units) 120, 121 communicating via communication link 122 and adapted to interface with a plurality of RCD devices at a switchboard or the like (not shown). Each interface module 120, 121 may include an interface such as interface module 13 and communicates with testing device 123 via communication link 124. Testing device 123 includes a battery power supply and communicates with digital computer 125 via communication link 126. Digital computer 125 includes control software incorporating advanced data gathering to facilitate smart or automatic selection of RCD devices for testing. Once tested, an associated load circuit may be immediately reset minimizing down time.

FIG. 8 is a block diagram showing multiple interface modules (relay units) 131, 133 communicating via communication link 132 and adapted to interface with a plurality of RCD devices at a switchboard or the like (not shown). Each interface module 131, 133 communicates with testing module 135 via communication link 134. Testing module 135 communicates with digital computer 137 via wireless communication link 136. Digital computer 137 includes control software incorporating advanced data gathering to facilitate smart or automatic selection of RCD devices for testing and data reporting. Once tested, the associated load circuit may be immediately reset minimizing down time.

Each testing device/module 13, 93, 103, 123, 135 may include trip test equipment developed by the present applicant, although the interface apparatus of the present invention may also be used with test equipment that meets required specifications and functionality produced by other manufacturers. Furthermore, although not shown, trip test equipment which includes analogue and digital displays, etc., may be incorporated into a bypass device to form a single unit which an operator can simply carry around from job to job.

Thus, it may be apparent that the present invention may provide for testing of RCD/RCCB devices without time-consuming field testing or the need for a technician or electrician. In this particular case, the means of selecting the protection device to be tested may be performed via control software interfaced to the appropriate relay board or boards. The apparatus may facilitate selective testing of devices and recording of results. Results may be made available either locally or remotely via an internet reporting site/facility.

Finally, it is to be understood that various alterations, modifications and/or additions may be introduced into the constructions and arrangements of parts previously described without departing from the spirit or ambit of the invention.

1.-31. (canceled)

32. Apparatus for testing a plurality of safety switches at a switch location such as a mains switchboard, wherein each safety switch is connected to a respective electrical load circuit including an active line and a neutral line, and wherein each safety switch of said plurality of safety switches does not include an on-board computer or processor and/or an ability to communicate to a testing device; said apparatus comprising:
a plurality of actuating devices, each actuating device being associated with a respective safety switch and load circuit and being adapted when activated to connect the respective safety switch and load circuit to a testing device for said testing, wherein the respective safety switch is not connected to said testing device until undergoing testing; and
a controller for selecting a single safety switch and associated load circuit from said plurality of safety switches and associated load circuits for said testing and for activating the associated actuating device so as to connect the selected safety switch and associated load circuit to said testing device for said testing;
wherein said testing device is adapted to communicate with a digital computer, wherein the digital computer includes computer software including a control application for controlling the testing device, and wherein the digital computer and control application communicate with the testing device to select a particular safety switch to allow it to be tested.

33. Apparatus according to claim 32 wherein each safety switch includes an RCD or RCCB device.

34. Apparatus according to claim 32 wherein each actuating device includes a controllable relay adapted to connect the selected safety switch and associated load circuit to said testing device.

35. Apparatus according to claim 32 wherein said controller includes a microprocessor or microcontroller.

36. Apparatus according to claim 32 including a line monitoring circuit for detecting an active line associated with a safety switch wherein said line monitoring circuit is associated with said controller to prevent a safety switch from being connected to said testing device until the associated line is clear of active voltage.

37. Apparatus according to claim 32 wherein said testing device is adapted to measure and/or record a trip time and/or a trip current associated with a safety switch.

38. Apparatus according to claim 32 wherein said testing device includes a manual device.

39. Apparatus according to claim 32 wherein said testing device includes an automatic device.

40. Apparatus according to claim 32 including means for interfacing to another like apparatus.

41. Apparatus according to claim 32 wherein said digital computer includes a portable PC or tablet computer.

42. Apparatus according to claim 32 including a facility to record the results of a test.

43. A method of testing a plurality of safety switches at a switch location such as a mains switchboard, wherein each safety switch is connected to a respective electrical load circuit including an active line and a neutral line, and wherein each safety switch of said plurality of safety switches does not include an on-board computer or processor and/or an ability to communicate to a testing device, said method comprising the steps of:
providing a plurality of actuating devices, each actuation device being associated with a respective safety switch and load circuit and being adapted when activated to connect the respective safety switch and load circuit to a testing device for said testing, wherein the respective safety switch is not connected to said testing device until undergoing testing; and
using a controller to select a single safety switch and associated load circuit from said plurality of safety switches and associated load circuits for said testing and to activate the associated actuating device so as to connect the selected safety switch and associated load circuit to said testing device for said testing;
wherein said testing device is adapted to communicate with a digital computer, wherein the digital computer includes computer software including a control application for controlling the testing device, and wherein the digital computer and control application communicate with the testing device to select a particular safety switch to allow it to be tested.

44. A method according to claim 43 wherein each safety switch includes an RCD or RCCB device.

45. A method according to claim 43 wherein each actuating device includes a controllable relay adapted to connect the selected safety switch and associated load circuit to said testing device.

46. A method according to claim 43 wherein the step of controlling is performed via a microprocessor or microcontroller.

47. A method according to claim 43 including detecting an active line associated with a safety switch and wherein the step of controlling is associated with the detecting step to prevent a safety switch from being connected to said testing device until the associated line is clear of active voltage.

48. A method according claim 43 wherein said testing device is adapted to measure and/or record a trip time and/or a trip current associated with a safety switch.

49. A method according to claim 43 wherein said testing device includes a manual or an automatic device.

50. A method according to claim 43 wherein said digital computer includes a portable PC or tablet computer.

51. A method according to claim 43 including a facility to record the results of a test.
